(19) United States
(12) Patent Application Publication
(10) Pub. No.: US 2020/0303482 A1
(43) Pub. Date: Sep. 24, 2020

(54) SEALING STRUCTURE, ORGANIC EL DISPLAY DEVICE, DISPLAY DEVICE, AND METHOD FOR MANUFACTURING DISPLAY DEVICE

(71) Applicants: SAKAI DISPLAY PRODUCTS CORPORATION, Sakai-shi, Osaka (JP); SHARP KABUSHIKI KAISHA, Sakai-shi, Osaka (JP)

(72) Inventors: KATSUHIKO KISHIMOTO, Sakai-shi, Osaka (JP); YUHKI KOBAYASHI, Sakai-shi, Osaka (JP)

(73) Assignees: SAKAI DISPLAY PRODUCTS CORPORATION, Sakai-shi, Osaka (JP); SHARP KABUSHIKI KAISHA, Sakai-shi, Osaka (JP); SHARP KABUSHIKI KAISHA, Sakai-shi, Osaka (JP)

(21) Appl. No.: 16/771,590

(22) PCT Filed: Dec. 22, 2017
(86) PCT No.: PCT/JP2017/046191

§ 371 Date: Jun. 10, 2020

(51) Int. Cl. H01L 27/32; H01L 51/52; G02F 1/1368; G02F 1/1343; H01L 51/56; G02F 1/1339

(52) U.S. Cl. CPC H01L 27/3267; H01L 51/5246; G02F 1/1368; G02F 1/13439; H01L 2227/323; H01L 51/56; G02F 1/13394; H01L 2251/556; G02F 2201/44; H01L 51/5253

(57) ABSTRACT

A sealing structure according to an embodiment of the present invention is provided with: first and second substrates that are opposed to each other; an electronic element that is formed between the first and second substrates; and a sealant that closes the gap between the first and second substrates, at the outer periphery of the electronic element, wherein the sealant includes a low-melting point glass material and a plurality of spacers, and the spacers have melting points higher than the softening point of the low-melting point glass material.

### TECHNICAL FIELD

The present invention relates to a sealing structure comprising an electronic element, an organic-EL display apparatus, a complex-type (a hybrid-type) display apparatus combining a reflecting-type liquid crystal display element and an organic-EL light-emitting element, and a method for manufacturing a display apparatus.

### BACKGROUND ART

With respect to an electronic element having the need to be shielded from outer air, such as an organic-EL light-emitting element in which an organic compound being easy to degrade due to moisture and an electrode being easy to decrease in performance due to oxidation is used, performance degradation of an element needs to be prevented by preventing penetration of moisture and oxygen. Therefore, in an image display apparatus in Patent document 1, for example, the space between an element substrate and a sealing substrate facing each other with a pixel portion sandwiched therebetween, the pixel portion comprising an organic compound, is doubly sealed at the surroundings of the pixel portion, using a first sealing agent and a second sealing agent being constituted of an epoxy-based resin. Moreover, in an organic light emitting diode display device in Patent Document 2, a sealant portion is formed in a sealing substrate as a partition wall of an internal filling agent, a sealing agent being formed of a glass frit is formed at the outer periphery of the sealant portion, and the space between a substrate on which a light-emitting element is formed and the sealing substrate is sealed by this sealing agent.

### PRIOR ART DOCUMENT

### Patent Documents

Patent Document 1: JP 2004-403337 A

Patent Document 2: JP 2010-103112 A

### SUMMARY OF THE INVENTION

### Problem to be Solved by the Invention

As described previously, in a conventional display apparatus comprising an organic compound, in order to seal a light-emitting element comprising the organic compound and being sandwiched by two substrates, a double seal using an epoxy resin or a sealing agent being formed of glass is formed. The interval between the two substrates depends on the height of a first sealing agent in the image display apparatus in Patent Document 1 and on the height of the sealant portion in the organic light-emitting diode display device in Patent Document 2. Therefore, in these sealing structures, when these heights vary in forming of the first sealing agent or the sealant portion, a variation is produced in the interval of the two substrates or, eventually, in the thickness of the display apparatus.

Therefore, an object of the present invention is to provide: a sealing structure to make it possible to protect an electronic element being formed between two substrates from moisture and oxygen and, even more, to make it possible to accurately control the gap between the two substrates; an organic-EL display apparatus in which the gap between the two substrates is controlled as such and an organic-EL light-emitting element can be protected; and a method for manufacturing a display apparatus in which the electronic element can be protected from moisture and oxygen as such and, even more, the gap between the two substrates is accurately controlled.

Another object of the present invention is to provide a complex-type display apparatus comprising both a liquid crystal display element and an organic-EL light-emitting element in which the organic-EL light-emitting element can be protected from penetration of moisture and oxygen and, even more, a reduction in picture quality in the liquid crystal display element, for example, can be suppressed.

### Means to Solve the Problem

A sealing structure according to a first embodiment of the present invention comprises a first substrate and a second substrate being arranged in an opposing manner; an electronic element being formed between the first substrate and the second substrate; and a sealing agent sealing a gap between the first substrate and the second substrate at an outer periphery of the electronic element, wherein the sealing agent comprises a low melting point glass material and a plurality of spacers; and the plurality of spacers has a melting point being higher than a softening point of the low melting point glass material.

An organic-EL display apparatus according to a second embodiment of the present invention comprises the sealing structure according to the first embodiment wherein the electronic element is an organic-EL light-emitting element.

A display apparatus according to a third embodiment of the present invention comprises a TFT substrate comprising a drive element being formed for each pixel of a display screen and a first insulating layer planarizing a surface above the drive element; a reflecting electrode for a liquid crystal display element, the reflecting electrode being formed above the first insulating layer in a first region of one pixel of the TFT substrate; an organic-EL light-emitting element being formed in a second region of the one pixel, the second region being adjacent to the first region and being above the first insulating layer of the TFT substrate, the organic-EL light-emitting element comprising a first electrode, an organic layer, a second electrode and an encapsulating layer; an opposing substrate comprising an opposing electrode opposing the reflecting electrode, the opposing substrate being arranged in an opposing manner to the TFT substrate; a liquid crystal layer being filled between the TFT substrate and the opposing substrate; and a sealing agent sealing a gap between the TFT substrate and the opposing substrate at an outer periphery of the liquid crystal layer, wherein the sealing agent comprises a low melting point glass material and a plurality of spacers; and the plurality of spacers has a melting point being higher than a softening point of the low melting point glass material.

A method for manufacturing a display apparatus according to a fourth embodiment of the present invention comprises: preparing a first substrate; forming, above the first substrate or on a surface of the first substrate, an electronic element to compose pixel; preparing a second substrate and arranging a sealing agent material on one of the first substrate and the second substrate; superimposing the first substrate and the second substrate with the sealing agent material being sandwiched between the first substrate and the second substrate; and adhering the first substrate and the second substrate with the sealing agent material, wherein, a material comprising a low melting point glass material and a plurality of granular bodies is used for the sealing agent material, the plurality of granular bodies having a melting point being higher than a softening point of the low melting point glass material and being mixed into the low melting point glass material; in arranging the sealing agent material, the sealing agent material is arranged at a portion, wherein the portion surrounds an electronic element-forming area for the electronic element when the first substrate and the second substrate are superimposed; and the sealing agent material is adhered to the first substrate and the second substrate by irradiation with laser light.

### Effects of the Invention

According to an embodiment of the present invention, it is possible to protect an electronic element formed between two substrates from moisture and oxygen and, even more, it is possible to accurately control the gap between the two substrates. Moreover, it is possible, in an organic-EL display apparatus, to control the gap between the two substrates and to protect an organic-EL light-emitting element. Furthermore, it is possible to manufacture a display apparatus in which an electronic element can be protected from moisture and oxygen as such and, even more, the gap between the two substrates can be accurately controlled. Moreover, according to another embodiment of the present invention, it is possible, in a complex-type display apparatus comprising both a liquid crystal display element and an organic-EL light-emitting element, to protect the organic-EL light-emitting element from penetration of moisture and oxygen and, even more, to suppress a reduction in picture quality in the liquid crystal display element.

### BRIEF DESCRIPTION OF THE DRAWINGS

FIG. 1A shows a plan view of one example of a sealing structure according to a first embodiment of the invention.

FIG. 1B shows a cross-sectional view along a line IB-IB in FIG. 1A.

FIG. 2A schematically shows one example of the configuration of a sealing agent material used in the sealing structure according to the first embodiment.

FIG. 2B schematically shows another example of the configuration of the sealing agent material used in the sealing structure according to the first embodiment.

FIG. 3A shows a plan view of the sealing agent material being formed by printing in manufacturing the sealing structure according to the first embodiment.

FIG. 3B shows a plan view of one example of a glass ribbon being fixed as the sealing agent material in manufacturing the sealing structure according to the first embodiment.

FIG. 3C shows a plan view of another example of the glass ribbon being fixed as the sealing agent material in manufacturing the sealing structure according to the first embodiment.

FIG. 4 shows a cross-sectional view of another example of the sealing structure according to the first embodiment of the invention.

FIG. 5 shows a cross-sectional view of a display apparatus according to a third embodiment of the invention.

FIG. 6 shows a flowchart of a method for manufacturing a display apparatus according to a fourth embodiment of the invention.

FIG. 7 shows one example of irradiation with laser light in the method for manufacturing the display apparatus according to the fourth embodiment of the invention.

### EMBODIMENT FOR CARRYING OUT THE INVENTION

In order to surely protect an electronic element being formed between two substrates from moisture and oxygen, it is required to strictly seal between the two substrates in the surroundings of the electronic element. Therefore, for such a sealing agent material, it is preferable to use a material such as glass, the material not generally transmitting moisture and oxygen. However, since glass is softened at the time of adhering a sealing agent being formed of glass and the two substrates, the height of the sealing agent is affected by the supply amount of the sealing agent, the viscosity and tension at the time of softening thereof, and the weight of the substrate being placed on the sealing agent. Therefore, it is extremely difficult to strictly control the height of the sealing agent, or, in other words, the interval of the two substrates, so that, as a result, it is also difficult to strictly control the thickness of an electronic apparatus such as a display apparatus being configured by such an electronic element.

However, not being able to strictly control the interval of the two substrates as such is not preferable in promoting thinning (downsizing) of an electronic apparatus. In particular, in a planar display for which thinning is required for incessantly as well as having flexibility with the progress of thinning is desired, it is often desired in many cases that the interval of the two substrates included in the planar display be small and then accurately controlled. In particular, with the below-described hybrid-type display comprising a liquid crystal display element and an organic-EL light-emitting element, an accurate control of the interval of the two substrates being sealed strictly is considered to be extremely important in obtaining a good picture quality thanks to the uniformity of a cell gap and a good reliability of the organic-EL light-emitting element thanks to little degradation by moisture. The present inventors have found such problems, have carried out intensive studies, and have found that the above-described problems can be solved by using a sealing agent comprising a low melting point glass material, and a spacer having a melting point being higher than the softening point of the low melting point glass material and being mixed into the low melting point glass material.

Below, a sealing structure, an organic-EL display apparatus, a display apparatus, and a method for manufacturing a display apparatus according to each embodiment of the invention are described with reference to the drawings. Material and shape of each constituting element, and relative positional relationships thereof according to embodiments described below are construed to be merely exemplary. The sealing structure, organic-EL display apparatus, display apparatus, and method for manufacturing the display apparatus are construed to be not limited thereby.

### (Sealing Structure and Organic-EL Display Apparatus)

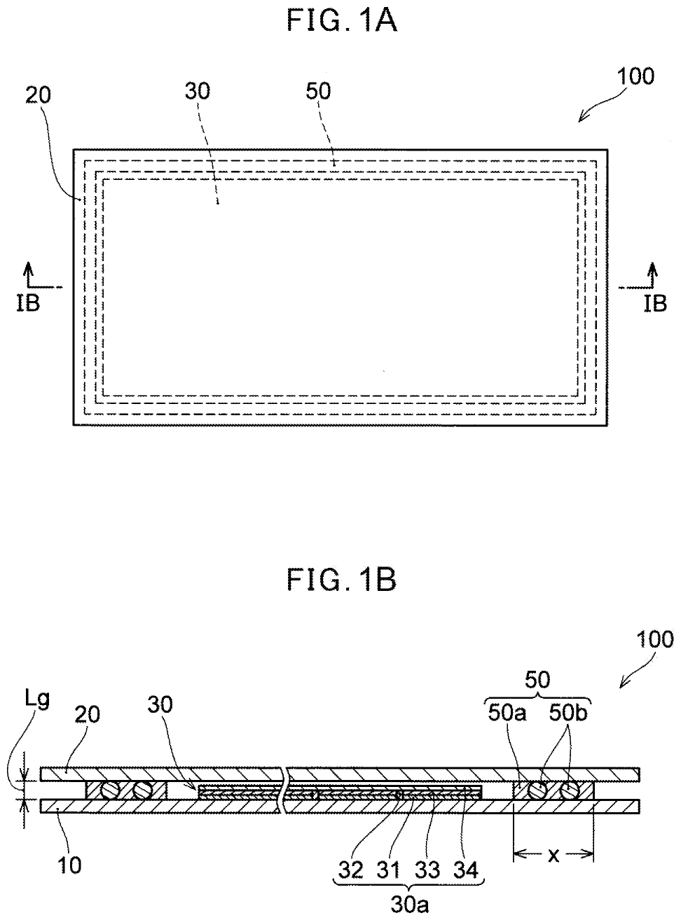

FIGS. 1A and 1B show a sealing structure 100 being one example of a sealing structure according to a first embodiment. FIG. 1B shows a cross-sectional view along a line IB-IB of FIG. 1A. In FIG. 1B, a cross section along the line IB-IB of FIG. 1A is shown in an enlarged manner, and, moreover, a central portion of the line IB-IB is omitted. As shown in FIGS. 1A and 1B, a sealing structure 100 comprises: a first substrate 10 and a second substrate 20 being arranged in an opposing manner; an electronic element 30 being formed between the first substrate 10 and the second substrate 20; and a sealing agent 50 sealing a gap between the first substrate 10 and the second substrate 20 at the outer periphery of the electronic element 30. The electronic element 30 is sealed in a generally hermetic manner between the first substrate 10 and the second substrate 20 by the sealing agent 50 sealing the gap between the first substrate 10 and the second substrate 20. The sealing agent 50 comprises a low melting point glass material 50a and a plurality of spacers 50b, the plurality of spacers 50b has a melting point being higher than the softening point of the low melting point glass material 50a. Therefore, as described below, the gap between the first substrate 10 and the second substrate 20 can be strictly controlled. In a case that a material being used for the spacer 50b does not have a clear melting point, the term “melting point” of the spacer 50b refers to the temperature at which the spacer 50b being in a solid state starts deforming.

The term “sealing structure” is a generic name for an electronic device in which the electronic element 30 is arranged between two substrates with the surroundings thereof being sealed. Moreover, the electronic element 30 means one or a plurality of electronic elements configuring an electronic device being generally referred to by the term “sealing structure”. For example, when the sealing structure is a lighting apparatus using an organic-EL light-emitting element (below also called merely an OLED), the electronic element 30 means one or a plurality of OLEDs configuring the above-mentioned lighting apparatus, while, when the sealing structure is a display apparatus, the electronic element 30 means a group of electronic elements such as a plurality of OLEDs each configuring each pixel. In a case that a plurality of electronic devices is manufactured in a pair of the first substrate 10 and the second substrate 20, the sealing agent 50 is formed in the surroundings of the electronic element 30 for each electronic device.

The first substrate 10 and the second substrate 20 are construed to be not particularly limited as long as they have airtightness. They can also be an insulating substrate, a semiconductor substrate, or a conductive substrate. Even when the insulating substrate is preferable in a case that the electronic element 30 (including an electrode being a component thereof) is formed on the surface of one substrate, the semiconductor substrate or the conductive substrate can be used with an insulating layer being formed on the surface thereof. Moreover, the first substrate 10 and the second substrate 20 can be a substrate having rigidity or a substrate having flexibility. Furthermore, the first substrate 10 and the second substrate 20 can be different types of substrates, for example, the semiconductor substrate and the insulating substrate. For the display apparatus or the light-emitting apparatus (lighting apparatus), a glass substrate, or a resin film such as polyimide can be used. While each of the first substrate 10 and the second substrate 20 is shown as a single-layer structure in FIG. 1B, a drive element (not shown) can be formed on the first substrate 10 and the second substrate 20.

While the electronic element 30 is construed to be not limited in particular, in a case that the electronic element 30 is an OLED comprising a material being easy to degrade due to moisture and oxygen, the sealing structure 100 according to the present embodiment is particularly effective. However, the electronic element 30 can be an electronic element into which a liquid crystal is sealed, such as a dye-sensitized solar cell and a liquid crystal display element (also called merely an LCD below). Moreover, the sealing structure 100 can comprise two or more and two or more types of electronic elements 30 such as a hybrid-type display apparatus comprising the LCD and the OLED to be described below.

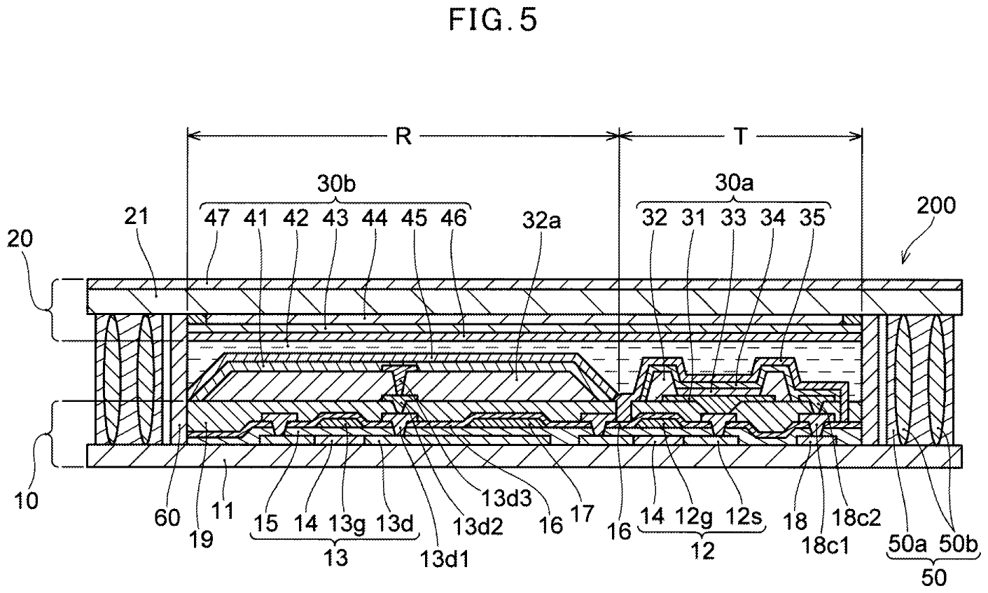

In the example shown in FIG. 1A, an organic-EL light-emitting element 30a is formed as the electronic element 30 on the first substrate 10 formed of glass. In other words, FIG. 1A also shows an organic-EL display apparatus according to a second embodiment. The organic-EL display apparatus according to the second embodiment comprises a sealing structure 100 and comprises the organic-EL light-emitting element 30a as an electronic element 30. The organic-EL light-emitting element 30a at least comprises a first electrode 31, an organic layer 33 being deposited at an area surrounded by an insulating bank 32 being formed to surround the first electrode 31, and a second electrode 34 being formed on the organic layer 33. While the organic-EL light-emitting element 30 is being simplified in FIG. 1A, the organic-EL display apparatus according to the second embodiment can at least comprise a plurality of drive elements 13 (see FIG. 5) being formed on the first substrate 10, and a plurality of organic-EL light-emitting elements 30a being formed on each one of the plurality of drive elements 13.

A sealing agent 50 surrounds the electronic element 30, and seals the gap between the first substrate 10 and a second substrate 20 at the surrounding of the electronic element 30. The sealing agent 50 is to hermetically seal the electronic element 30 being formed between the first substrate 10 and a second substrate 20 to make sure that the electronic element 30 does not degrade due to moisture and oxygen. Therefore, a glass material, not resins such as an epoxy resin, is used for the sealing agent 50. The width (thickness) x of the sealing agent 50 is, for example, greater than or equal to 0.5 mm and less than or equal to 2.0 mm. If the sealing agent 50 has this degree of width, it is believed that no major problem occur with respect to hermetic sealing.

As the electronic element 30 is sealed in between the first substrate 10 and the second substrate 20, temperature can be increased only to the extent to not damage the electronic element 30 in adhering the sealing agent 50 to the first substrate 10 and second substrate 20. Therefore, the sealing agent 50 comprises a low melting point glass material 50a having a low softening point (temperature at which the sealing agent 50 becomes a so-called rubber state). The low melting point glass has the softening point decreased by mixing a low melting point oxide into a glass composition, and has the softening point being generally approximately 350° C. to 600° C., or greater. In the present embodiment, the low melting point glass material having the low softening point is preferable since substrates at which the electronic element 30 is formed are bonded with the low melting point glass material. On the other hand, when the low melting point glass crystallizes, the adhesive strength between the sealing agent 50, and the first substrate 10 and the second substrate 20 could decrease, so that the higher the crystallization starting temperature is, the more preferable it is. In other words, the softening point of the low melting point glass is preferably decreased by mixing the low melting point oxide into the glass composition to such a degree that the crystallization starting temperature does not fall below the temperature to be reached by heating at the time of bonding the sealing agent 50 and the each substrate. Moreover, taking into account that a film material formed of a polyimide resin can be used for the first substrate 10, the softening point of the low melting point glass material 50a to be used for the sealing agent 50 is preferably greater than or equal to 400° C. and less than or equal to 500° C.

For example, the vanadium-based low melting point glass (V₂O₅) and the phosphorus acid salt-based low melting point glass (P₂O₅) can be mixed at the weight ratio (V₂O₅/P₂O₅) of generally around. 2.5 and, moreover, approximately 15 mass % of barium oxide can be added thereto to obtain a low melting point glass having the softening point of approximately 450° C. In other words, in a case of the sealing agent 50 comprising such material-based low melting point glass and the additive material, the sealing agent 50 can be heated so as to reach the temperature of approximately 450° C. to 500° C. while bringing the sealing agent 50 into contact with the each substrate to soften the sealing agent 50 once and firmly adhere the sealing agent 50 to each substrate. In particular, the vanadium-based low melting point glass having a high light absorbability in visible to infrared regions can be softened by local heating by using laser light, for example, as described below. Therefore, the sealing agent 50 can be softened relatively easily without excessively increasing the temperature in the immediate surroundings of the electronic element 30. The low melting point glass material 50a included in the sealing agent 50 is construed to be not limited to the vanadium-based low melting point glass or the phosphorus acid salt-based low melting point glass, or the mixture thereof. For example, the low melting point glass material 50a can be the boric acid salt-based low melting point glass or the telluride-based low melting point glass, or the mixture thereof. Moreover, the softening point of the low melting point glass material 50a can be a temperature out of the range of greater than or equal to 400° C. and less than or equal to 500° C. In short, it suffices that the low melting point glass material 50a have a temperature at which it starts to change to a rubber-like state or a paste-like state in which it can adhere to the first substrate 10 and the second substrate 20 without having a marked influence on the electronic element 30 with respect to the light-emitting performance and life.

In the present embodiment, as shown in FIG. 1B, the sealing agent 50 comprises a spacer 50b being formed using a material having a melting point being higher than the softening point of the low melting point glass material 50a, along with the low melting point glass material 50a. The spacer 50b is scattered in the sealing agent 50 and interposed between the first substrate 10 and the second substrate 20 and thereby specifying a length Lg of the gap between both substrates. In other words, the length Lg of the gap between the first substrate 10 and the second substrate 20 can be determined by the dimension (the width or the length) in the direction along the length Lg. Therefore, in order to suppress dispersion in the length Lg of the sealing structure 100, it is preferable that the width, the length, or the diameter in the direction of the length Lg be uniform in the plurality of spacers 50b.

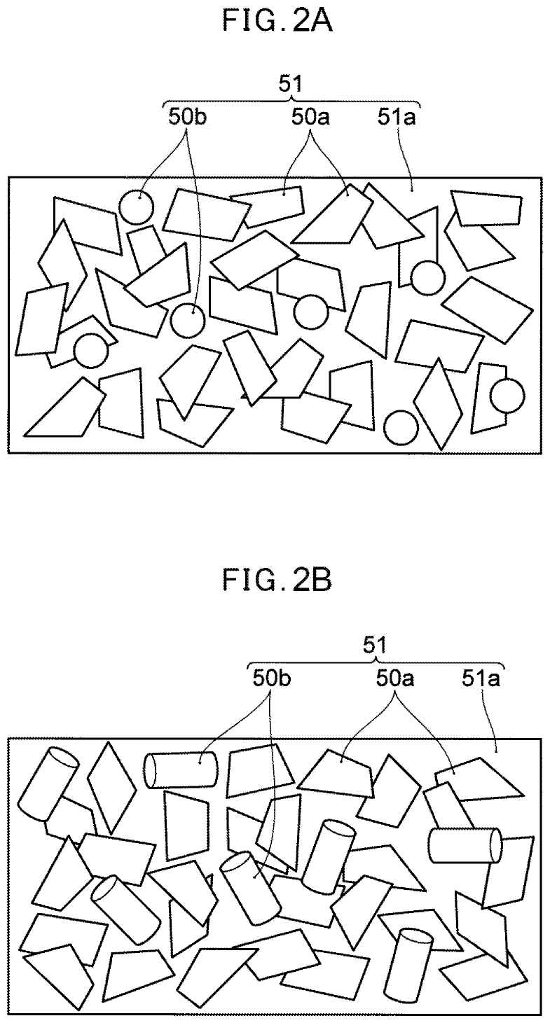

Moreover, it is preferable that the spacer 50b be uniformly scattered in the sealing agent 50. For example, the spacer 50b is a granular body being scattered in the low melting point glass material 50a. In such a case, the length Lg of the gap between the first substrate 10 and the second substrate 20 can be limited by the grain diameter of the spacer 50b. In other words, a granular body having a grain diameter being appropriate for the spacer 50b can be selected to obtain a desired length Lg at the gap between the first substrate 10 and the second substrate 20. The term “granular body” includes not just merely a perfectly-spherical grain (see FIG. 2A), but also an ellipsoidal, a columnar (see FIG. 2B), or a fiber-like granular substance. In other words, the spacer 50b can be a granular substance being generally referred to as a beads spacer or a fiber spacer. For example, while the term “grain diameter” refers to the diameter of the granular body for a spherical granular body, it refers to the diameter, or the length of a short axis or one side of the cross section being orthogonal to the longitudinal direction of the granular body for an ellipsoidal, a columnar, or a fiber-like granular body. For example, the dispersion range of the “grain diameter” of the granular body to be used for the plurality of spacers Sob is preferably less than or equal to approximately 0.1 μm. The dispersion being at such a degree makes it possible to realize, with the sealing structure 100 according to the present embodiment, even a liquid crystal display apparatus in which a strict control is required for the length of the gap between a substrate comprising a pixel electrode (for example, a first electrode) and a substrate comprising an opposing electrode (for example, a second electrode).

The spacer 50b can be included in the sealing agent 50 at an arbitrary content rate. The greater the content rate of the spacer 50b in the sealing agent 50 is, the more preferable it is in that the gap between the first substrate 10 and the second substrate 20 can be uniformly held at an adhering part by the sealing agent 50. On the other hand, the sealing agent 50 needs to also comprise the low melting point glass material 50a having a sufficient amount so that it can adhere to the first substrate 10 and the second substrate 20 with a required strength. Therefore, the content rate of the spacer 50b in the sealing agent 50 is preferably greater than or equal to 5 mass % and less than or equal to 30 mass % and more preferably greater than or equal to 15 mass % and less than or equal to 25 mass %. It is considered that the spacer 50b being included in this range of content rate makes it possible to adhere the sealing agent 50 to the first and second substrates 10 and 20 with a sufficient strength, and, even more, makes it possible to also suppress the non-uniformity and dispersion of the gap between the first substrate 10 and the second substrate 20 to a practically allowable range.

Material of the spacer 50b is construed to be not limited in particular as long as the spacer 50b has a melting point being higher than the softening point of the low melting point glass material 50a. However, the spacer 50b is preferably constituted of an inorganic substance since the spacer 50b should have a melting point being higher than the softening point, of the low melting point glass material 50a, reaching approximately 400° C. as described previously. For example, the spacer 50b is constituted of silicon dioxide (silica; SiO₂) having a melting point of greater than or equal to 1600° C. or quartz being a crystallized material thereof, aluminum oxide (alumina: Al₂O₃) having a melting point of greater than or equal to 2000° C., or calcium carbonate (CaCO₃) having a melting point of greater than or equal to 800° C.

As described previously, downsizing and thinning of electronic apparatuses are being sought permanently. While such a trend is marked in the field of planar displays, an accurate control of the length between two substrates configuring a display is required not only with requirements in the marketplace, but also in the aspect of improving the performance thereof. For example, in a display apparatus, the interval between a substrate comprising a pixel electrode and a substrate comprising an opposing electrode can be strictly controlled to suppress display non-uniformity caused by non-uniformity of cell gaps. Moreover, in an organic-EL display apparatus as well, in terms of thinning, improvement in flexibility, and reduction in material cost, requirements for narrowing the gap between a substrate comprising a drive element and an organic light-emitting element (for example, a first substrate) and a protecting substrate or a sealing substrate (for example, a second substrate) and for strictly controlling the length of the gap associated with the narrowing are considered to increase. The sealing structure 100 according to the present embodiment makes it possible to respond to such requirements. In other words, the spacer 50b exists even at the time of softening the low melting point glass material 50a at the time of bonding the first substrate 10 and the second substrate 20, so that the length Lg of the gap between both substrates is never brought to less than or equal to the grain diameter of the spacer 50b. Moreover, by moderately pressing both substrates toward each other at the time of bonding thereof, it is possible to easily prevent the length Lg of the gap from being longer than the grain diameter of the spacer 50b. Therefore, the length Lg of the gap between the first substrate 10 and the second substrate 20 can be strictly controlled. As granular bodies constituting the spacer 50b, in a case that the granular bodies are formed of SiO₂, for example, ones having the grain diameter at a submicron level can be formed and, moreover, ones having the grain diameter of up to approximately several hundred μm can be formed by growing a seed grain.

The length Lg of the gap between the first substrate 10 and the second substrate 20 in the organic-EL display apparatus according to the second embodiment, the organic-EL display apparatus comprising the sealing structure 100 according to the first embodiment, can be greater than or equal to 5 μm and less than or equal to 50 μm, for example. In a conventional organic-EL display apparatus, the gap between a substrate comprising a drive element and an organic light-emitting element, and a sealing substrate or a protecting substrate is not set to be narrow as such. However, the gap between both substrates can be strictly controlled in such a short length by including the spacer 50b into the sealing agent 50 as in the present embodiment. As a result, it is possible to contribute to further thinning and/or flexibility improvement of the organic-EL display apparatus.

The low melting point glass material 50a is prepared in a state of a glass frit in a form of several tens μm cube fine powder, for example, and, as described previously, is softened by heating using laser light and solidified as the temperature decreases. In other words, the low melting point glass material 50a in the sealing agent 50 of the sealing structure 100 can be a solidified material of glass frit being once softened. FIGS. 2A and 2B show examples of the configuration of a sealing agent material 51 comprising the low melting point glass material 50a being prepared as a glass frit as such and to become the sealing agent 50 by solidifying after being softened once. As shown in FIGS. 2A and 2B, the sealing agent material 51 comprises the low melting point glass material 50a in a state of a plurality of grass frits and the plurality of spacers 50b, each being the granular body which has been constituted of the previously-described inorganic substance such as quartz.

In the examples in FIGS. 2A and 2B, the sealing agent material 51 further comprises a binder 51a comprising an organic solvent and is prepared in a paste form by mixing the low melting point glass material 50a being glass frit-like, the spacer 50b, and the binder 51a. In FIG. 2A, the spacer 50b has a shape of a nearly perfect sphere. On the other hand, in FIG. 2B, the spacer 50b has a nearly-columnar shape. As described previously, the spacer 50b of the granular body is construed to be not limited to the examples of FIGS. 2A and 2B, so that it can be an ellipsoidal or fiber-like granular substance. However, the length of a portion, of the spacer 50b being a granular body, to be sandwiched when being sandwiched between the first substrate 10 and the second substrate 20 is preferably uniform for the plurality of spacers 50b as described previously and, for example, the dispersion range thereof is preferably less than or equal to 2% of the length of the portion to be sandwiched and more preferably less than or equal to 1% of the length of the portion. The term “the length of the portion to be sandwiched” of the spacer 50b between the first substrate 10 and the second substrate 20 is, for example, the diameter of the spacer 50b having a nearly spherical shape, the diameter of a cross section being orthogonal to the length direction of the columnar-shaped spacer 50b, or the length of the short axis or the diameter of the cross section being orthogonal to the length direction of the ellipsoidal spacer 50b.

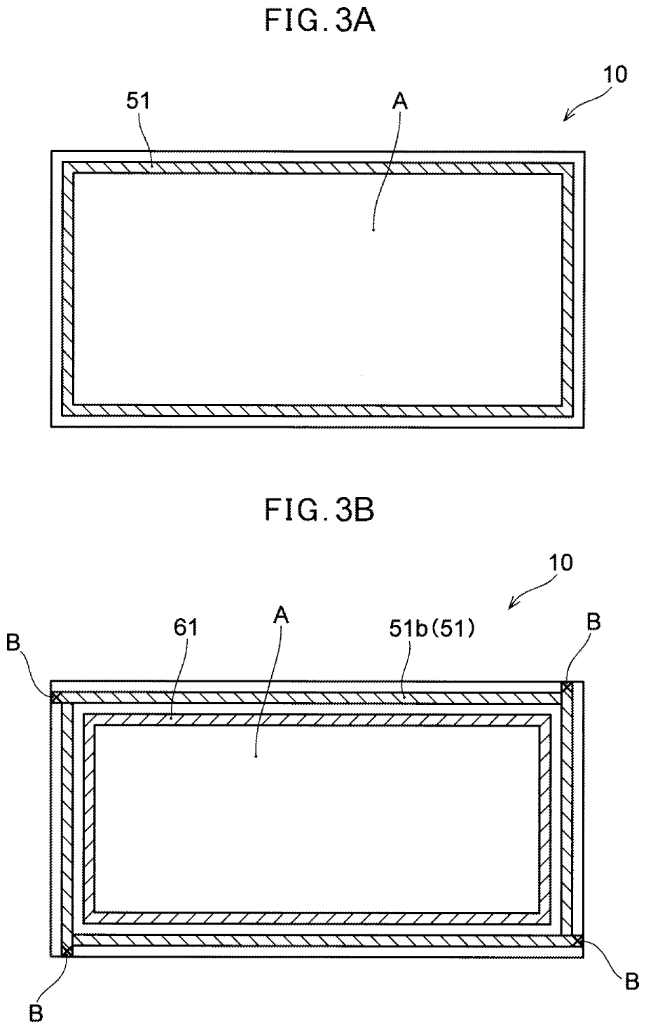

Arrangement of the sealing agent material 51 to the first substrate 10 or the second substrate 20 is described using FIGS. 3A to 3C. As shown in FIG. 3A, for example, the sealing agent material 51 being prepared in a paste form as described previously is applied to a given portion on a substrate (for example, the first substrate 10) using screen printing or using a dispenser. The term “a given portion” refers to a portion which is supposed to surround an electronic element-forming area A. The sealing agent material 51 can be applied to either one of the first substrate 10 and the second substrate 20. In other words, the sealing agent material 51 can be applied to a substrate on which the electronic element 30 (see FIG. 1A) is formed or can be formed on a substrate (for example, the second substrate 20 in a case that the electronic element 30 is formed on the first substrate 10) to be adhered to the substrate on which the electronic element 30 is formed. Therefore, in a case that the sealing agent material 51 is arranged on the substrate on which the electronic element 30 is formed, the term “a portion which is supposed to surround the electronic element-forming area A” refers to a part that surrounds the electronic element-forming area. A concurrently with applying of the sealing agent material 51. On the other hand, in a case that the sealing agent material 51 is arranged on a substrate on which the electronic element 30 is not formed, the term “a part which is supposed to surround the electronic element-forming area A” is a part that surrounds the electronic element 30 at the time of superimposing the substrate on which the sealing agent material 51 is arranged and the substrate on which the electronic element 30 is formed in a post-process. In a case that a barrier rib material 61 (see FIG. 3B) described below is arranged, the sealing agent material 51 is arranged in separation with the barrier rib material 61 at the outer periphery of the barrier rib material 61. Then, the other substrate (for example, the second substrate 20) is superimposed with the sealing agent material 51 being sandwiched and laser light is applied thereto. As a result, the sealing agent material 51 is heated up to the temperature being greater than or equal to the softening point of the low melting point glass material 50a, the sealing agent material 51 is adhered to each substrate and the sealing agent 50 is formed as well. For irradiation with the laser light, various laser lights can be used as described below.

The sealing agent material 51 does not necessarily have to be a low melting point glass being applied in a paste form. For example, as shown in FIGS. 3B and 3C, a glass ribbon 51b can be used as the sealing agent material 51 (FIGS. 3B and 3C show the below-described barrier rib material 61 along with the sealing agent material.) In other words, the sealing agent material 51 can be arranged by bonding the glass ribbon 51b to a given part of one of the first substrate 10 and the second substrate 20. Even in this case, the glass ribbon 51b comprises the previously-described low melting point glass material 50a and granular bodies constituting the spacer 50b. In other words, the glass ribbon 51b is formed by pouring the molten low melting point glass material 50a into a mold, or shaping a glass frit being prepared in a paste form and solidifying the shaped glass frit, and, in such a forming step, the granular body such as quartz is mixed into the low melting point glass material 50a as the spacer 50b. In a case of forming the glass ribbon 51b from a paste, the glass ribbon 51b not encapsulating air bubbles or gas and, eventually, the sealing agent 50 not encapsulating air bubbles or gas can be obtained by evaporating the binder 51a (see FIG. 2A) at the time of forming the glass ribbon 51b.

In a case that the glass ribbon 51b is used, for example, the glass ribbon 51b is bonded using an adhering agent to, for example, a given portion for forming the sealing agent 50 on one of two substrates, for example, the first substrate 10 (the given portion being an adhering portion of each substrate to be adhered to the other substrate with the sealing agent material 51). Then, after superimposing the second substrate 20, by irradiation with laser light, the sealing agent 50 is formed and is adhered to each substrate as well. In this case, as shown in FIGS. 3B and 3C, it suffices that the adhering agent be applied to a part (an adhering part B), not the entire surface of the glass ribbon 51b.

Specifically, as shown in FIGS. 3B and 3C, an adhering portion with the sealing agent material 51 is divided into a plurality of parts (for example, each side of a rectangular substrate), and the glass ribbons 51b having the length in accordance with the respective divided parts are prepared. Then, an adhering agent (not shown) is applied to only the adhering part B of one end (example of FIG. 3B) or both ends (example of FIG. 3C) of the glass ribbon 51b, and each glass ribbon 51b is arranged to and adhered to each of the divided parts of the adhering portion on the first substrate 10 or the second substrate 20. In this case, the glass ribbon 51b is formed such that the glass ribbon 51b is longer, by the length of the adhering part B, than the length of each of parts into which the adhering portion has been divided. Then, as shown in FIGS. 3B and 3C, the adhering part B is arranged at a part being opposite to the electronic element-forming area A with respect to the adhering portion. In other words, the adhering part B is positioned at the exterior of a portion to be adhered using laser light after the first substrate 10 and the second substrate 20 are superimposed. In this way, even in a case that an adhering agent (not shown) being applied to the adhering part B releases gas (moisture or oxygen) at the time of a temperature increase due to irradiation with laser light, penetration of the gas into the electronic element-forming area A can be prevented by the sealing agent 50 (see FIG. 1) to be formed along with the temperature increase. Therefore, it is considered that degradation of the electronic element 30 can be prevented.

In the example shown in FIG. 3B, the adhering agent is applied to only one end of the glass ribbon 51b. The other end of the glass ribbon 51b butts against another glass ribbon 51b, and, when adhered, is bonded to such another glass ribbon 51b to be integrated therewith. As a result, even when the temperature of the glass ribbon 51b increases in adhering to the substrates, gas generated from the adhering agent due to the temperature increase is to be released to the exterior of the sealing agent 50.

In the example shown in FIG. 3C, both ends of the glass ribbon 51b are slightly extended and folded by 90 degrees. The glass ribbon 51b is arranged such that the portion being folded is positioned at the exterior of the adhering portion. Therefore, in the same manner as the example in FIG. 3B, the adhering part B is to be at the exterior of the sealing agent material 51, so that, even when gas is generated from the adhering agent in adhering with laser light, the gas is never sealed into the electronic element-forming area A. Even more, the glass ribbon 51b is adhered to the substrates at both ends of the glass ribbon 51b, making it possible to very stably adhere the glass ribbon 51b.

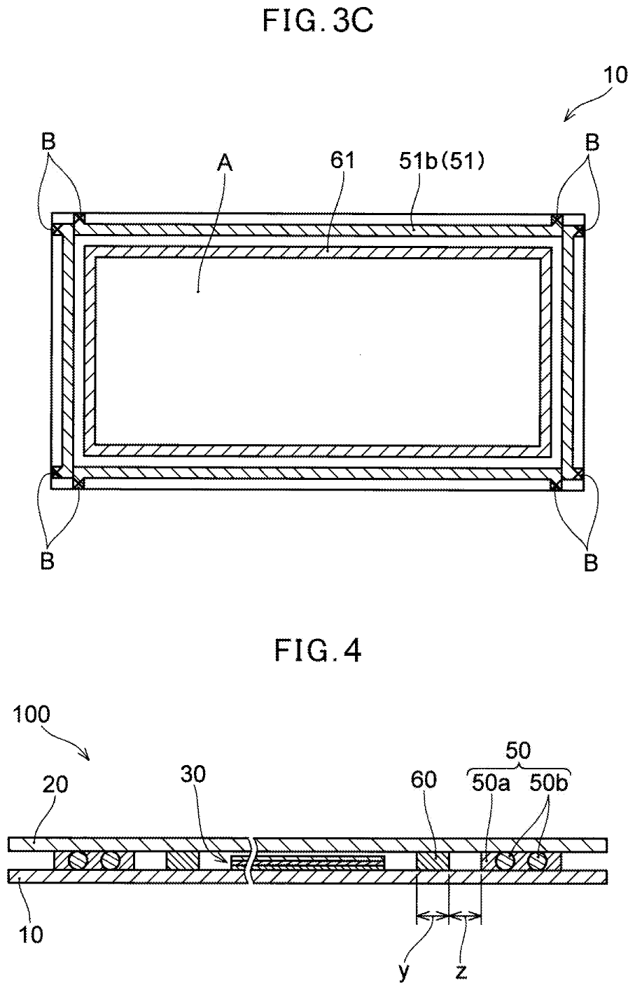

The sealing agent material 51 comprising the low melting point glass material 50a as described previously can soften at a relatively low temperature and adhere to the first and second substrates 10, 20. However, a heat insulating means is preferably provided between the electronic element 30 and the sealing agent 50 to surely prevent degradation of the electronic element 30 due to heat and to sufficiently soften the low melting point glass material 50a at a sufficiently high temperature. Moreover, in a case that the liquid display apparatus is configured with the sealing structure 100, before the first substrate 10 and the second substrate 20 are adhered via the sealing agent 50, a liquid crystal is filled between these two substrates. Therefore, it is necessary to provide a bank (a barrier rib) to intercept the outflow of the liquid crystal being filled at least until the gap between the two substrates has been sealed at the surroundings of the electronic element 30 by the sealing agent 50. In FIG. 4, another example of the sealing structure 100 according to the present embodiment is shown, the sealing structure 100 comprising the barrier rib 60 as such.

As shown in FIG. 4, the barrier rib 60 being in separation from the sealing agent 50 and surrounding the electronic element 30 is formed between the sealing agent 50 and the electronic element 30. In the same manner as the sealing agent 50, the barrier rib 60 is formed so as to surround the electronic element 30. Therefore, even in a case that the electronic element 30 comprises a liquid material such as liquid crystal, the liquid material can be retained at the interior of the barrier rib 60 and the liquid material can be prevented from directly contacting with the sealing agent 50 as well. Moreover, conduction of heat to the electronic element 30 at the time of heating for adhesion of the sealing agent 50 can be suppressed. Therefore, degradation of the electronic element 30 can further be suppressed. The thickness y of the barrier rib 60 is greater than or equal to 0.1 mm and less than or equal to 1.0 mm, for example. It is considered that the barrier rib 60 having this degree of thickness allow the heat conductance to be suppressed effectively and, even more, the possibility of causing a marked capsizing of a display apparatus comprising the sealing structure 100 be small as well. For the same reason with the above, the interval z between the sealing agent 50 and the barrier rib 60 is preferably greater than or equal to 0.5 mm and less than or equal to 1.0 mm. This is because it has been confirmed that the heat conduction can be substantially prevented by bringing the interval to at least 0.5 mm and, on the other hand, no significant changes are seen with respect to the effect of suppressing the heat conductance even when the interval of 1 mm or more is provided. The barrier rib 60 is not aimed at sealing the electronic element 30, so that the barrier rib 60 does not necessarily have to be adhered to the first substrate 10 and the second substrate 20.

As the barrier rib material 61 (see FIGS. 3B and 3C) that can be used as the barrier rib 60, an inorganic material such as glass, ceramics, a metal oxide, a metal, or a semiconductor, for example, is exemplified. As the glass, a glass frit or a glass ribbon of the low melting point glass being used as the sealing agent 50 as described previously can be used. Even in a case that a different inorganic material such as ceramics or a metal oxide is used, the barrier rib 60 can be formed by turning such a material into fine powder in the same manner as the glass frit to mix the fine powder with an organic solvent or an adhering agent.

As described previously, the barrier rib 60 does not need to have a sealing function, so that, even when the barrier rib material 61 is fine powder and eventually porous, for example, it suffices that the fine pores thereof be very small and the barrier rib 60 can prevent the flow of the liquid material such as liquid crystal being a part of the electronic element 30. Rather, the porous barrier rib 60 can also be preferable in that heat conduction in the barrier rib 60 is suppressed. Therefore, the barrier rib 60 comprising a large number of fine pores can be formed by making fine powder of the inorganic material pasty using a binder and thermally curing the past after printing. It is considered that, even though the binder does not disappear completely, there be no generation of such gas as to degrade the characteristics of the electronic element 30 as long as the amount of the binder is less than or equal to 10% of the total volume.

In a case of a structure in which the barrier rib 60 adheres to only one of the first substrate 10 and the second substrate 20, gas generated in curing is never sealed in between the two substrates as along as the barrier rib material 61 is cured before superimposing the first and second substrates 10 and 20 even when a thermosetting resin is used for the barrier rib material 61. Therefore, the barrier rib 60 is not limited to the inorganic material. In this case, it is preferable to sufficiently increase an interval z between the sealing agent 50 and the barrier rib 60, for example to set the interval z to be greater than or equal to 0.7 mm and less than or equal to 1 mm such that the barrier rib 60 is not heated by heat generated in heating the sealing agent material 51.

In a case that an organic material is used for the barrier rib material 61, a bonding resin being used to seal two substrates in manufacturing a conventional liquid crystal display apparatus, for example, epoxy resin, epoxy acrylate, urethane acrylate, or silicone resin can be used. These materials can be an ultraviolet curing resin or a thermosetting resin depending on a polymerization initiator to be added. Moreover, the thermosetting resin can be a delay curing resin. In such a case, by performing a thermal treatment at a location being distant from the electronic element 30 (for example, a substrate on which the electronic element 30 is not formed), it is possible to prevent a temperature increase and generation of gas in the vicinity of the electronic element 30. Moreover, in a case that an ultraviolet curing resin or a visible light curing resin is used, the barrier rib material 61 can be cured without a temperature increase or generation of gas as well. The barrier rib 60 can be adhered to both of the first substrate 10 and the second substrate 20. However, in such a case as well, with the sealing structure 100 according to the present embodiment, the gap between the first substrate 10 and the second substrate 20 is controlled by the spacer 50b. Therefore, the height of the barrier rib 60 is preferably less (lower) than the grain diameter of the spacer 50b, and the deficit height of the barrier rib 60 in such a case is preferably being compensated by increasing the amount of the adhering agent.

### (Display Apparatus)

Herein below, a complex-type display apparatus 200 comprising an OILED 30a and an LCD 30b as electronic elements 30 is described with reference to FIG. 5.

A display apparatus 200 according to a third embodiment of the invention comprises a TFT substrate 10 comprising a driving TFT 13 being formed for each pixel of a display screen and a first insulating layer (a so-called planarizing layer) planarizing a surface above the driving TFT 13; a reflecting electrode 41 for an LCD 30b, the reflecting electrode 41 being formed above the first insulating layer 19 in a first region R of one pixel of the TFT substrate (the first substrate) 10; an OLED 30a being formed in a second region T of the one pixel, the second region T being adjacent to the first region R and being above the first insulating layer 19 of the TFT substrate 10, the OLED 30a comprising a first electrode 31 an organic layer 33, a second electrode 34, and an encapsulating layer 35; an opposing substrate (a second substrate) 20 comprising an opposing electrode (a transparent electrode) 43 opposing the reflecting electrode 41 and being arranged in an opposing manner to the TFT substrate 10; a liquid crystal layer 42 being filled between the TFT substrate 10 and the opposing substrate 20; and a sealing agent 50 sealing a gap between the TFT substrate 10 and the opposing substrate 20 at the outer periphery of the liquid crystal layer 42, wherein the sealing agent 50 comprises a low melting point glass material 50a and a plurality of spacers 50b; and the plurality of spacers 50b has a melting point being higher than a softening point of the low melting point glass material 50a.

Moreover, in the example in FIG. 5, a barrier rib 60 to separate the sealing agent 50 and the liquid crystal layer 42 is provided between the TFT substrate 10 and the opposing substrate 20, and the sealing agent 50 and the barrier rib 60 are in separation.

While the barrier rib 60 and the sealing agent 50 are formed in the surroundings of the one LCD 30b and the one OLED 30a, in practice, a sub-pixel comprising a set of the LCD 30b and OLED 30a is formed for each of red (R), green (G), and blue (B), and, moreover, a plurality of pixels each one of which is composed of the sub-pixels consisting of the R, G, and B are formed in a matrix. According to the present embodiment, the entire elements being formed in the matrix are to be the electronic elements 30, and the sealing agent 50 and the to barrier rib 60 are formed to surround them. In FIG. 5, the thickness direction of the TFT substrate 10 and the opposing substrate 20 is emphasized such that each constituting element is shown in an easy-to-understand manner. Therefore, while the cross section of the spacer 50b is being drawn in an ellipse in which the major axis is much longer than the minor axis, the spacer 50b in the example in FIG. 5 is a spherical granular body having a circular cross section in the same manner as that in FIG. 1B.

In the display apparatus 200 according to the present embodiment, a reflecting-type LCD 30b is formed in a first region. R of one pixel, and a light-emitting element such as the OLED 30a, for example, is formed in a second region T being adjacent to the first region R of the one pixel. The reflecting-type LCD 30b comprises the reflecting electrode 41, the liquid crystal layer 42, the transparent electrode 43 (opposing electrode), a color filter (CF) 44, liquid crystal alignment layers 45, 46, respectively formed on the surfaces of the reflecting electrode 41 and the transparent electrode 43, and a polarizer 47. The liquid crystal layer 42, transparent electrode 43, and polarizer 47 are formed at the entire display apparatus 200, extending toward the second region T. Moreover, the OLED 30a comprises the first electrode 31, a second insulating layer 32 also referred to as a so-called insulating bank, the second insulating layer 32 defining the first electrode 31 and a light-emitting region, the organic layer 33, the second electrode 34, and an encapsulating layer 35 to cover the surroundings thereof. While the second insulating layer 32 is formed also above the first insulating layer 19 in the first region R with the same material and in substantially the same thickness, the second insulating layer 32 in the first region R is separated from the second insulating layer 32 in the second region T, so that the second insulating layer in the first region R is called a third insulating layer 32a.

For the TFT substrate 10, TFTs such as the driving TFT (a thin-film transistor) 13 and a current supplying TFT 12, and a wiring such as a bus line (not shown) are formed on one surface of the insulating substrate 11 comprising a resin film such as polyimide, or a glass substrate, for example, and the first insulating layer 19 called a so-called planarizing layer to planarize the surface thereof is formed. While each of the TFTs is formed by a semiconductor layer 14 such as a polysilicon or an amorphous semiconductor, a gate insulating layer 15, gate electrodes 13g, 12g, a passivation layer 16, explanations of details thereof will be omitted. In FIG. 5, an auxiliary capacitance electrode 17 being connected in parallel to the liquid crystal layer 42 of the LCD 30b is formed.

Moreover, in FIG. 5, a source 12s of the current supplying TFT 12 is connected to an anode electrode 31 of the OLED 30a. A cathode electrode 34 of the OLED 30a is connected to a cathode bus line 18 by via contacts 18c1 and 18c2. The first insulating layer 19 can be formed with an organic material such as polyimide, or an inorganic material such as SiO₂ or SiNₓ using CVD method. A drain 13d of the driving TFT 13 is connected to the reflecting electrode 41 through contacts 13d1 to 13d3, while the source 12s of the current supplying TFT 12 is connected to the first electrode 31 for the OLED 30a. FIG. 5 shows the structure of elements conceptually, so that not all of each element is shown accurately.

For the opposing substrate 20, the color filter 44, the opposing electrode 43, and the liquid crystal alignment layer 46 are formed on an insulating substrate 21 such as glass or a transparent (light-transmitting) film, for example.

The opposing substrate 20, and the TFT substrate 10 on which the OLED 30a is formed are adhered using the sealing agent 50 at the surroundings of the OLED 30a and an LCD 30b with a certain interval being secured such that the reflecting electrode 41 and the opposing electrode 43 face each other. A liquid crystal material to be a part of the electronic element 30 is sealed in between both substrates 10 and 20, so that the liquid crystal layer 42 is formed, and the polarizer 47 is provided on the surface, of the opposing substrate 20, being opposite to the liquid crystal layer 42.

Adhering of the sealing agent 50, and the TFT substrate 10 and the opposing substrate 20 is carried out by the same method as the previously-described method in the explanations of the sealing structure 100 according to the first embodiment. As the sealing agent 50 comprises the spacer 50b, the length of the gap between the TFT substrate 10 and the opposing substrate 20 can be strictly controlled even when the low melting point glass material 50a softens at the time of adhering. The sealing agent 50 adheres to a region, on the opposing substrate 20, at which the opposing electrode 43, the color filter 44, and the liquid crystal alignment layer 46 are not formed, and, moreover, adheres to a region, on the TFT substrate 10, at which the first insulating layer 19 and each TFT are not formed. Therefore, in the example in FIG. 5, specifically, the length of the gap between the insulating substrate 11 of the TFT substrate 10 and the insulating substrate 21 of the opposing substrate 20 can be controlled most strictly. However, in association therewith, the gap between the reflecting electrode 41 and the opposing electrode 43, for example, can also be accurately controlled in the extreme. The sealing agent 50 can be adhered to the insulating substrates 11 and 21 via the first insulating layer 19 or the color filter 44, for example.

The OLED 30a is formed in the second region T of one pixel and, as shown in FIG. 5, is formed by the first electrode 31 being formed in the second region T on the surface of the first insulating layer 19, the second insulating layer 32 being formed in the surroundings of the first electrode 31 to surround the first electrode 31, the organic layer 33 formed on the first electrode 31 being surrounded by the second insulating layer 32, the second electrode 34 on the organic layer 33 being formed on almost the whole OLED 30a, and the encapsulating layer 35 covering the surroundings of the second electrode 34.

The first electrode 31 is formed as an anode electrode, for example. In the case of the present embodiment, the display screen is to be viewed from the upper end of FIG. 5, so that the first electrode 31 is formed as a reflecting electrode and has a structure such that all of lights emitted are radiated upward. Therefore, the first electrode 31 is formed with a light-reflecting material, for example, a deposited layer of ITO/APC/ITO being selected based on the work function relationship with the organic layer 33.

The second electrode 32 is formed to define a light-emitting region of the OLED 30a and also to prevent the first electrode 31 and the second electrode 34 from being in contact and electrically connected with each other. The organic layer 33 is deposited on the first electrode 31 being surrounded by the second insulating layer 32. The second insulating layer 32 is formed with a resin such as polyimide or an acrylic resin, for example. For the significance of aligning the heights of the first region R and the second region T, the second insulating layer 32 is also formed in the first region R in which the LCD 301) is formed.

The organic layer 33 is deposited on the first electrode 31 being surrounded by the second insulating layer 32 by vapor deposition or an application method such as inkjet. The organic layer 33 being shown as one layer in FIG. 5 is formed as a plurality of layers with various materials being deposited. Specifically, a positive-hole injection layer and a positive-hole transport layer are formed inn order on the first electrode 31, for example. Moreover, above these layers, a light-emitting layer selected in accordance with the light-emitting wavelength is formed by doping, to Alq₃, an organic fluorescent material of red or green for red color, green color, respectively, for example. As a blue color material, a USA-based organic material is used. An electron transport layer is further formed above the light-emitting layer. Moreover, an electron injection layer can also be provided. These respective layers, each having approximately several tens of nm in thickness, can be deposited.

The second electrode 34 is formed on the surface of the organic layer 33. The second electrode (for example, the cathode electrode) 34 is formed on almost the whole OLED 30a. The second electrode 34 is formed with a light-transmitting material, for example, a thin-film Mg—Ag eutectic film. The encapsulating layer (TFE) 35 comprising an inorganic insulating layer of Si₃N₄, or SiO₂, for example, is formed on the surface of the second electrode 34 by one deposited layer, or two or more deposited layers. The encapsulating layer 35 encapsulates the second electrode 34 and the organic layer 33.

As shown in FIG. 5, the liquid crystal layer 42 and the opposing electrode 43 are formed above the OLED 30a as well. However, in the OLED 30a region, there is no reflecting electrode 41 corresponding to the opposing electrode 43. Thus, the same situation as in a case of the voltage applied to the opposite surfaces of the liquid crystal layer 42 as described below being off occurs. In other words, while a normally-black state is obtained for external light, light emitted in the OLED 30a passes through the circular polarizer 47 without any change since the liquid crystal layer 42 is vertically-aligned, which is the same as having no liquid crystal layer 42. Therefore, an image displayed by light emission in the OLED 30a is visually recognized from the front end as it is.

The LCD 30b is formed as a reflecting-type LCD with the reflecting electrode 41 being formed at the whole of the first region R of approximately a half of one pixel, the liquid crystal layer 42, the opposing electrode 43, and the polarizer (circular polarizer) 47. The liquid crystal layer 42 is formed at the whole including the second region T. The reflecting electrode 41 is a so-called a pixel electrode, and is formed at almost the whole first region R. The reflecting electrode 41 is formed above the third insulating layer 32a being simultaneously formed with the same material as the second insulating layer 32 of the OLED 30a as described previously. The reflecting electrode 41 is formed with deposited layers of Al (aluminum) being greater than or equal to 0.05 μm and less than or equal to 0.2 μm and IZO (indium-zinc-oxide) being greater than or equal to 0.005 μm and less than or equal to 0.05 μm, for example. In forming the second insulating layer 32 of the OLED 30a, the third insulating layer 32a is formed with the same material as that for the second insulating layer 32. In this way, the third insulating layer 32a being formed in the first region R makes it possible to bring the height of the underlayer of the liquid crystal layer 42 closer between the two regions R and T.

The liquid crystal layer 42 comprises a liquid crystal composition, and various display modes such as an ECB (electronically controlled birefringence) mode, for example, can be used therein. The liquid crystal layer 42 shuts off incident light or allows incident light to pass, for each pixel in cooperation with the polarizer 47 in accordance with applying or stopping of the voltage between the reflecting electrode 41 and the opposing electrode 43. For the ECB mode, it is preferable that the liquid crystal layer 42 be formed so as to have the thickness such that when the voltage is turned on, a ¼ wavelength phase difference occurs until light transmits the liquid crystal layer 42 and reaches the reflecting electrode 41. In the display apparatus 200 according to the present embodiment, as the sealing agent 50 comprises the spacer 50b, the gap between the opposing substrate 20 and the TFT substrate 10 can be strictly controlled. As a result, the thickness of the liquid crystal layer 42 can also be controlled accurately.

Alignment of the liquid crystal alignment layer 46 being formed at the opposing substrate 20 and alignment of the liquid crystal alignment layer 45 being formed at the TFT substrate 10 are formed so as to differ by an angle of 90 degrees from each other, for example. In a case that the liquid crystal alignment layers 45 and 46 are formed such that the liquid crystal molecules are vertically aligned with the voltage not being applied between the opposite surfaces of the liquid crystal layer 42, for example, when the voltage of greater than or equal to a threshold value is not applied between the reflecting electrode 41 and the opposing electrode 43, reflected light of external light does not exit to the exterior, and thereby providing a black display state, or, in other words, a normally-black type.

A circular polarizer, for example, is used for the polarizer 47. The circular polarizer is formed as a combination of a linear polarizer and a ¼ wavelength retardation plate, for example. Moreover, a ½ wavelength retardation plate can also be used together to possess the ¼ wavelength condition with respect to a wide range of wavelengths. When the voltage of greater than or equal to a threshold value is not applied between the reflecting electrode 41 and the opposing electrode 43 so that the liquid crystal layer 42 is vertically aligned, external light passes through the liquid crystal layer 42 as it is to be reflected by the reflecting electrode 41, causing a reversal of light polarization from right circularly-polarized light to left circularly-polarized light. Therefore, external light returning to the polarizer 47 cannot pass through the polarizer 47, causing a black display to be obtained. On the other hand, when the voltage of greater than or equal to the threshold value is applied to the liquid crystal layer 42 to cause the liquid crystal molecules to be horizontally-aligned, external light is further shifted on its phase by ¼ wavelength at the liquid crystal layer 42, and therefore, the external light being reflected in the reflecting electrode 41 can transmit the polarizer 47, causing a white display to be obtained. The polarizer 47 is construed to be not limited to the circular polarizer, so that it can also be a linear polarizer according to the display mode.

The sealing agent 50 is the same as the sealing agent 50 used in the previously-described sealing structure 100 according to the first embodiment and the sealing agent 50 use in the previously-described organic-EL display apparatus according to the second embodiment, and comprises the low melting point glass material 50a, and the spacer 50b having a melting point being higher than the softening point of the low melting point glass material 50a. Therefore, as described previously, the length of the gap between the TFT substrate 10 and the opposing substrate 20 can be strictly controlled. In particular, with the hybrid-type display apparatus 200 comprising the OLED 30a and the LCD 30b as exemplified in FIG. 5, a high degree of sealing property with respect to the OLED 30a is required, and, at the same time, a strict control of the gap between the two substrates 10 and 20 is required to maintain and improve the picture quality of the LCD 30b. Therefore, the display apparatus 200 according to the present embodiment is particularly suitable as such a hybrid-type display apparatus, because the display apparatus 200 comprises the sealing agent 50 being configured by a glass material (the lour melting point glass material 50a) with a high degree of sealing property compared to that of a resin and including the spacer 50b having a melting point being higher than the softening point of the glass material. In the display apparatus 200 as well, the sealing agent 50 is formed, as shown in FIG. 3A as referred to previously, at the surroundings of the OLED 30a and the LCD 30b on the TFT substrate 10 or on the opposing substrate 20 using a glass frit paste or a glass ribbon and these substrates are superimposed to adhere the sealing agent 50 to the substrates thereafter. The whole of the glass frit, or the low melting point glass material 50a of at least a bonding portion of the glass ribbon to the substrates 10 and 20 is softened by irradiation with laser light so that the sealing agent 50 is adhered to the TFT substrate 10 and the opposing substrate 20.

The barrier rib 60 also is the same as the barrier rib 60 that can be provided in the previously-described sealing structure 100 according to the first embodiment, and can be formed in separation with the sealing agent 50 with the same method using the same material as that in the case of the sealing structure 100. While the barrier rib 60, and the LCD 30b or the OLED 30 are in contact with each other in the example in FIG. 5, the barrier rib 60 and these electronic elements can be in contact with or in separation from each other.

### (Method for Manufacturing a Display Apparatus)

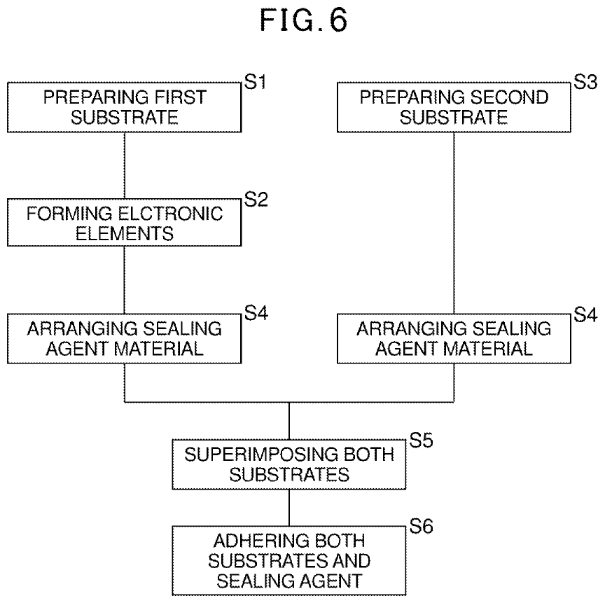

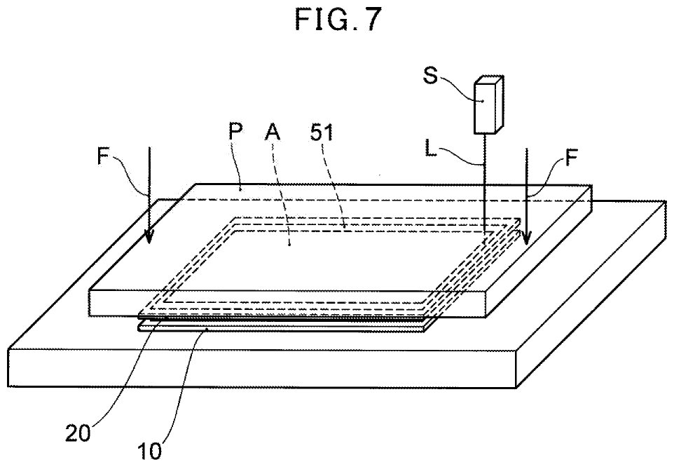

Herein below, a method for manufacturing a display apparatus according to a fourth embodiment of the invention is described with continued reference to FIG. 5 and with reference to FIGS. 6 and 7. The method for manufacturing a display apparatus according to the present embodiment comprises: preparing a first substrate 10 (S1 in FIG. 6); forming, above the first substrate 10 or on a surface of the first substrate 10, an electronic element 30 to compose pixels (S2); preparing a second substrate 20 (S3) and arranging a sealing agent material 51 (see FIG. 3A) on one of the first substrate 10 and the second substrate 20 (S4); superimposing the first substrate 10 and the second substrate 20 with the sealing agent material 51 being sandwiched between the first substrate 10 and the second substrate 20 (S5); and adhering the first substrate 10 and the second substrate 20 with the sealing agent material 51 (S6). Here, for the sealing agent material 51, a material comprising a low melting point glass material 50a and a plurality of granular bodies is used. The plurality of granular bodies has a melting point being higher than the softening point of the low melting point glass material 50a and being mixed into the low melting point glass material 50a. Moreover, in arranging the sealing agent material 51, the sealing agent material 51 is arranged at a portion. The portion is a portion to surround an electronic element-forming area A (see FIG. 3A) when the first substrate 10 and the second substrate 20 are superimposed. And, the sealing agent material 51 is adhered to the first substrate 10 and the second substrate 20 by irradiation with laser light. Each one of the plurality of granular bodies constitutes a spacer 50b of the sealing structure 100 according to the first embodiment described previously.

The above-described respective steps do not have to be carried out in this order, so that step S3 can be carried out first, for example. Moreover, step S4 is carried out in either one of the first substrate 10 and the second substrate 20. In other words, as described previously, the sealing agent material 51 can be arranged in one of the first substrate 10 and the second substrate 20, can be applied to a substrate on which the electronic element 30 is formed, or can be formed on a substrate to be adhered to the substrate on which the electronic element 30 is formed. Therefore, the term “a portion to surround an electronic element-forming area A” refers to a part of the first substrate 10 surrounding the electronic element 30 in a case that the sealing agent material 51 is arranged in the first substrate 10 on which the electronic element 30 is formed, while the term refers to a part to surround the electronic element 30 when the first substrate 10 and the second substrate 20 are superimposed in step S5 in a case that the sealing agent material 51 is arranged in the second substrate 20.

Below, with primary preference to FIG. 5, a method for manufacturing a display apparatus according to the present embodiment is described using manufacturing of the display apparatus 200 according to the third embodiment as an example, the display apparatus 200 comprising an OLED 30a and an LCD 30b as the electronic elements 30. However, a display apparatus comprising only one of the OLED 30a and the LCD 30b, for example, can be manufactured using the method for manufacturing according to the present embodiment. Therefore, among formation steps for respective constituting elements in the explanations below, formation step for any of elements constituting only the OLED 30a and elements constituting only the LCD 30b in the display apparatus 200 can be omitted in accordance with the type of the display apparatus to be manufactured. For example, in a case that a liquid crystal display apparatus is to be manufactured, forming of a third insulating layer 32a and each of elements constituting the OLED 30a can be omitted. Moreover, in a case that an organic-EL display apparatus is to be manufactured, forming of each of elements constituting the LCD 30b such as an opposing electrode 43 and a reflecting electrode 41, liquid crystal alignment layers 45 and 46, and a liquid crystal layer 42 can be omitted.

First, the first substrate (TFT substrate) 10 is prepared (S1). Specifically, using a general method of forming a TFT, a semiconductor layer 14 and a bus line (not shown) are formed above an insulating substrate 11, and, moreover, a gate insulating layer 15, a drain 13d and a gate electrode 13g of a driving TFT 13, a source 12s and a gate electrode 12g of a current supplying TFT 12, and an auxiliary capacitance electrode 17 are formed. Moreover, on the surface thereof, a passivation layer 16 comprising, for example, SiNₓ and a contact 13d1 are formed, and a first insulating layer 19 is formed using a polyimide resin, or an inorganic layer of SiO₂, for example.

Then, the reflecting electrode 41 for the LCD 30b, and the OLED 30a are formed above or on the surface of the TFT substrate 10 (S2). Specifically, a first electrode (anode electrode) 31 for the OLED 30a is formed with a deposited layer of ITO/APC (Ag—Pd—Cu alloy)/ITO. A contact 13d2 to connect with the drain 13d of the driving TFT 13 is also formed in the first insulating layer 19. Then, using a polyimide resin or an acrylic resin, a second insulating layer 32 is formed such that it surrounds the first electrode 31 and comprises a projection. For example, a resin layer is formed on the entire surface over the substrate in a liquid state, and, thereafter, the second insulating layer 32 is formed in a desired shape at a desired location by patterning the resin layer. In the patterning step for the second insulating layer 32, a contact hole connecting to the contact 13d2 of a first region R is formed, causing a third contact 13d3 to be formed. Moreover, a trench can also be formed in the first insulating layer 19 being exposed by dividing the resin layer into the second insulating layer 32 and the third insulating layer 32a.

Thereafter, an organic layer 33 is formed by vapor deposition, or printing such as inkjet method, and a second electrode 34 to be a cathode electrode is formed, by vapor deposition using a vapor-deposition mask, on the almost entire surface of the OLED 30a including the projection of the second insulating layer 32 and the organic layer 33.

Thereafter, an encapsulating layer 35 is formed with an inorganic layer of SiNₓ or SiO₂. The encapsulating layer 35 is preferably formed with multiple layers comprising at least two layers. The encapsulating layer 35 is formed using CVD or ALD (atomic layer deposition) method. The encapsulating layer 35 can be formed so as to reach the first region R. In forming the encapsulating layer 35, the material thereof is embedded also into the trench formed in the first insulating layer 19, and the encapsulating layer 35 is joined to an inorganic layer, such as the passivation layer 16, being an underlayer of the first insulating layer 19. The encapsulating layer 35 can be formed on the entire surface, and, then, patterned by etching, or it can be deposited at only a desired location using a mask.

Thereafter, a reflecting electrode (pixel electrode) 41 for the LCD 30b is formed on the surface of the third insulating layer 32a of the first region R. The reflecting electrode 41 is also electrically connected to the contact 13d3. The reflecting electrode 41 is formed with Al and IZO, for example. As the reflecting electrode 41 is formed in almost a half of one pixel except for the entire surface of the OLED 30a, it can be formed by patterning of a reflecting layer formed on the whole surface thereof by vapor deposition. Moreover, the liquid crystal alignment layer 45 is deposited on the reflecting electrode 41. With the above, preparing of the first substrate 10 is completed.

In the meantime, separately from the first substrate 10, the second substrate (opposing substrate) 20 is prepared (S3). The second substrate 20 is prepared by depositing the light-transmitting opposing electrode 43, and, as needed, a color filter 44 and the liquid crystal alignment layer 46 on an insulating substrate 21 such as a glass plate or a resin film. Here, since the explanations are given with manufacturing of the display apparatus 200 comprising both the LCD 30b and the OLED 30a as an example, the opposing electrode 43 and so forth are formed. However, as described previously, in a case that the organic-EL display apparatus is manufactured, forming of the opposing electrode 43 and so forth can be omitted.

Thereafter, the sealing agent material 51 (see FIG. 3A) is arranged on either one of the first substrate 10 and the second substrate 20 (S4). The sealing agent material 51 is arranged at a portion that surrounds the electronic element-forming area A when the first substrate 10 and the second substrate 20 are superimposed. The sealing agent material 51 comprises the low melting point glass material 50a. With the low melting point glass material 50a, the plurality of granular bodies is mixed, which is to be a plurality of spacers 50b that has a melting point being higher than the softening point of the low melting point glass material 50a and restricts the gap between the first substrate 10 and the second substrate 20 when sandwiched by these substrates. Preferably, the sealing agent material 51 is used in which the content rate of the plurality of granular bodies to be the spacer 50b in the entirety of the plurality of granular bodies and the low melting point glass material 50a is greater than or equal to 5 mass % and less than or equal to 30 mass %. Such a sealing agent material 51 can be used to make it possible to obtain a sufficient adhering strength between the sealing agent 50 and the first substrate 10 as well as the second substrate 20, and it is possible to strictly control the gap between the first substrate 10 and the second substrate 20.

As described previously, the sealing agent material 51 can be prepared in a paste form and applied. In other words, as shown in FIGS. 2A and 2B previously-referred, along with using a glass frit as the low melting point glass material 50a, a columnar body or a spherical body constituted of an inorganic substance can be used as a granular body to be the spacer 50b. Then, the sealing agent material 51 being prepared in a paste form using a binder 51a can be prepared, and the sealing agent material 51 can be arranged by applying the glass frit (the low melting point glass material 50a) and the granular body to the first substrate 10 or the second substrate 20 using printing or dispensing.

Moreover, the sealing agent material 51 can be prepared in a form of a glass ribbon and can be arranged by fixing one end or both ends thereof to the first substrate 10 or the second substrate 20 using an adhering agent. In other words, a glass ribbon 51b (see FIGS. 3B and 3C) comprising a plurality of granular bodies to be the spacer 50b and the low melting point glass material 50a can be used for the sealing agent material 51. Then, the sealing agent material 51 can be arranged by bonding the glass ribbon 51b to a given portion of the first substrate 10 or the second substrate 20. In this case, arranging and bonding of the glass ribbon 51b can preferably be carried out as described previously with reference to FIGS. 3B and 3C. In other words, an adhering portion to be adhered with the sealing agent material 51 is divided into plural parts and the glass ribbon 51b is arranged to each of the divided parts. Then, one end or both ends of the glass ribbon 51b is adhered to the first substrate 10 or the second substrate 20 at a part being opposite to the electronic element-forming area A (see FIGS. 3B and 3C) with respect to the adhering portion. In this way, it is considered that penetration of gas into the electronic element-forming area A can be prevented and degradation of the electronic element 30 can be prevented. Preferably, as shown in FIG. 5, the sealing agent material 51 is directly bonded to the insulating substrates 11 and 21 by exposing these substrates. This is because it can be considered that an adequate adhering is easily obtained.

In a case that the display apparatus 200 shown in FIG. 5 is manufactured, a barrier rib material 61 (see FIGS. 3B and 3C) is arranged at a peripheral edge portion of the electronic element-forming area A before or after arranging the sealing agent material 51. The barrier rib material 61 can be arranged on either one of the first substrate 10 and the opposing substrate 20. The barrier rib material 61 is formed such that the reflecting electrode 41 for the LCD 30b and the OLED 30a are housed in a region surrounded by the barrier rib material 61 when the first substrate 10 and the second substrate 20 are superimposed. While an inorganic material is preferable for the barrier rib material 61 as described previously, a resin material such as an epoxy resin can be used. Moreover, the barrier rib material 61 can be arranged in a paste by application, or the barrier rib material 61 can be adhered after prepared in a ribbon form. In a case that the barrier rib material 61 in the paste form is applied, it is cured thereafter by heating or ultraviolet irradiation to form the barrier rib 60. The height of the barrier rib material 61 can be selected in accordance with the interval of the two substrates to be bonded together. However, as described previously, the height is preferably less than the grain diameter of the granular body to be the spacer 50b in not interfering with controlling the gap of the first substrate 10 and the second substrate 20 by the spacer 50b.

In a case that the barrier rib 61 is arranged, the barrier rib 61 is arranged in separation from the sealing agent material 51. Preferably, the sealing agent material 51 and the barrier rib material 61 are separated by a distance of greater than or equal to 0.5 mm and less than or equal to 1.0 mm. This is because it is considered that separating by this degree of distance causes heat conduction to be effectively suppressed as described previously and, even more, also does not cause a marked upsizing of the display apparatus 200 so much. The barrier rib material 61 and the sealing agent material 51 can be arranged in separate substrates.

In a case that the display apparatus 200 shown in FIG. 5 is manufactured, a liquid crystal material (a liquid crystal composition) is dropped onto the forming region of the LCD 30b and the OLED 30a that is surrounded by the barrier rib 60. The dropping of the liquid crystal composition is preferably carried out under vacuum atmosphere. This is because it is easier to discharge air bubbles entrapped in the liquid crystal material in dropping.

Then, the first substrate 10 and the second substrate 20 are superimposed with the sealing agent material 51 being sandwiched between the first substrate 10 and the second substrate 20 (S5). After they are superimposed, it is preferable to bring the surrounding pressure to the atmospheric pressure or a higher pressure than that since pressure can be exerted uniformly onto the two substrates. In this case, nitrogen atmosphere (100% N₂ atmosphere), or dry air atmosphere is preferable. This is because it is possible to cause nitrogen or dry air to penetrate the interior of the sealing agent 50 as the sealing with the sealing agent 50 has not been carried out yet at this time. Therefore, dry air having a dew point of less than or equal to −50° C. is particularly preferable.

Then, the sealing agent material 51 is adhered to the first substrate 10 and the second substrate 20 by irradiation with laser light (S6). Irradiation with laser light causes the low melting point glass material 50a included in the sealing agent material 51 to soften and to adhere to the first substrate 10 and the second substrate 20. For example, laser light is emitted such that the sealing agent material 51 reaches the temperature of approximately 450° C. to 500° C. As a light source for the laser light, excimer laser having the wavelength of approximately greater than or equal to 190 nm and less than 350 nm, YAG laser having the wavelength of 1064 nm, or CO₂ laser having the wavelength of 10.6 μm can be used. The wavelength of various laser lights can be converted in accordance with the wavelength band for which the low melting point glass material 50a included in the sealing agent material 51 has a good absorption property.

In the method for manufacturing a display apparatus according to the present embodiment, the sealing agent material 51 comprises a granular body to be the spacer 50b, therefore, it is preferable to carry out irradiation with laser light with the first substrate 10 and the second substrate 20 being pressed toward each other. In other words, it is preferable that irradiation with laser light to the sealing agent material 51 be carried out while exerting compressive force, on the sealing agent material 51, in the thickness direction of the first substrate 10 and the second substrate 20. Exerting such a force makes it possible to control the length of the gap between the first substrate 10 and the second substrate 20 to a length being substantially equal to the grain diameter of the spacer 50b. The force to be exerted to the first substrate 10 or the second substrate 20 at this time is preferably a force being greater than or equal to 0.1 N/cm² and less than or equal to 15 N/cm². It is considered that, with such a degree of force, the first substrate 10 and the second substrate 20 can be brought to be in contact with the spacer 50b and, even more, no excessive damages are provided to these substrates.

Moreover, a thin plate material or film is often used for the first substrate 10 and the second substrate 20, therefore, it is preferable to perform the irradiation with laser light using a pressing jig that can press the first substrate 10 and the second substrate 20 over the entirety thereof. In this way, even in a case that warp occurs in the first substrate 10 or the second substrate 20, the gap between both substrates can be made uniform all over the first substrate 10 and the second substrate 20. FIG. 7 shows an example of a step of the irradiation with laser light using such a pressing jig P.

In the example shown in FIG. 7, a plate-shaped pressing jig P is placed on the first substrate 10 and the second substrate 20 being superimposed and a force F is exerted via the pressing jig P. Then, the sealing agent material 51 is irradiated, via the pressing jig P, with a laser light L emitted from a light source S and having a given wavelength at the top of the pressing jig P. The light source S is moved along an arrangement portion of the sealing agent material 51. For example, the sealing agent material 51 is irradiated with laser light of 25 W power being moved at the velocity of 5 mm/sec. Therefore, the sealing agent material 51 is heated in all around the surroundings of the electronic element-forming area A and the low melting point glass material 50a is solidified after being softened once. As a result, the sealing agent material 51 adheres to the first substrate 10 and the second substrate 20 and the sealing agent 50 to seal the gap between the first substrate 10 and the second substrate 20 at the surroundings of the electronic element-forming area A is formed. The power and moving velocity of laser light are construed to be not limited to the above-mentioned power and velocity.

The force F can be exerted to the pressing jig P by an arbitrary loading mechanism (not shown). The pressing jig P is formed using a material having good permeability for laser light used in the irradiation and having a moderate heat resistance and rigidity. While quartz having a high transmittance to light in the ultraviolet ray region is used as a material for the pressing jig P, for example, the material is construed to be not limited thereto. Moreover, the wavelength of the laser light L can be selected in accordance with the wavelength band for which the material of the pressing jig P exhibits a good permeability. For example, in a case that the pressing jig P being formed using quartz is used, the laser light L having a wavelength of greater than or equal to 300 nm and less than or equal to 2000 nm is preferably used. For example, excimer laser or YAG laser as described previously is used. In a case that YAG laser is used, the laser light L being converted from the fundamental wave to ½ wavelength or ⅓ wavelength can be emitted. The pressing jig P can have the light-shielding property except for a part which is irradiated with the laser light L. However, it is preferable that at least a portion covering the electronic element-forming area A should have light-transmitting property, in that the state of the OLED 30a and the LCD 30b during the irradiation with the laser light can be checked.

In a case that the display apparatus 200 shown in FIG. 5 is manufactured, the polarizer 47 is bonded to a surface being opposite to the opposing electrode 43 of the second substrate 20 after adhering the first substrate 10 and the second substrate 20 to each other with the sealing agent material 51. As a result, the hybrid-type display apparatus 200 in which the reflecting-type LCD 30b is formed in the first region R and the OLED 30a is formed in the second region T is obtained.

### SUMMARY

(1) A sealing structure according to a first embodiment of the present invention comprises: a first substrate and a second substrate being arranged in an opposing manner; an electronic element being formed between the first substrate and the second substrate; and a sealing agent sealing a gap between the first substrate and the second substrate at an outer periphery of the electronic element, wherein the sealing agent comprises a low melting point glass material and a plurality of spacers; and the plurality of spacers has a melting point being higher than a softening point of the low melting point glass material.

According to the configuration of (1), it is possible to protect an electronic element formed between two substrates from moisture and oxygen and, even more, it is possible to accurately control the interval between the two substrates.

(2) In the sealing structure according to (1) mentioned above, the low melting point glass material can be a solidified material of glass frit being once softened; and the plurality of spacers can be a granular body constituted of an inorganic substance and being mixed into the glass fit. In that case, a sealing agent comprising a spacer can be easily provided.

(3) In the sealing structure according to (1) or (2) mentioned above, the softening point of the low melting point glass material can be greater than or equal to 400° C. and less than or equal to 500° C., and the plurality of spacers can be formed using quartz. In that case, heat stress to the electronic element can be suppressed and, even more, since there is generally no softening of the spacer at the time of adhesion of the two substrates, the gap between the two substrates can be controlled further strictly.

(4) In the sealing structure according to any one of (1) to (3) mentioned above, a content rate of the plurality of spacers in the sealing agent can be greater than or equal to 5 mass % and less than or equal to 30 mass %. In that case, the sealing agent can be adhered with a sufficient strength to the first and second substrates and, even more, non-uniformity and dispersion of the gap between the first substrate and the second substrate can also be suppressed.

(5) In the sealing structure according to any one of (1) to (4) mentioned above, a barrier rib being separated from the sealing agent and surrounding the electronic element can be formed between the sealing agent and the electronic element. In this way, conduction of heat into an electronic element-forming area can be suppressed.

(6) An organic-EL display apparatus according to the second embodiment of the present invention comprises the sealing structure according to any one of (1) to (5); wherein the electronic element is an organic-EL light-emitting element. According to this configuration, it is possible, in an organic-EL light-emitting element, to control the gap between two substrates and to protect an organic-EL light-emitting element from moisture.

(7) A display apparatus according to a third embodiment of the present invention comprises a TFT substrate comprising a drive element being formed for each pixel of a display screen and a first insulating layer planarizing a surface above the drive element; a reflecting electrode for a liquid crystal display element, the reflecting electrode being formed above the first insulating layer in a first region of one pixel of the TFT substrate; an organic-EL light-emitting element being formed in a second region of the one pixel, the second region being adjacent to the first region and being above the first insulating layer of the TFT substrate, the organic-EL light-emitting element comprising a first electrode, an organic layer, a second electrode and an encapsulating layer; an opposing substrate comprising an opposing electrode opposing the reflecting electrode, the opposing substrate being arranged in an opposing manner to the TFT substrate; a liquid crystal layer being filled between the TFT substrate and the opposing substrate; and a sealing agent sealing a gap between the TFT substrate and the opposing substrate at an outer periphery of the liquid crystal layer, wherein the sealing agent comprises a low melting point glass material and a plurality of spacers; and the plurality of spacers has a melting point being higher than a softening point of the low melting point glass material.

(7) According to the configuration of (7), in a complex-type display apparatus comprising both a liquid crystal display element and an organic-EL light-emitting element, it is possible to protect the organic-EL light-emitting element from penetration of moisture and oxygen and, even more, to suppress a reduction in picture quality in the liquid crystal display element.

(8) In the display apparatus according to (7) mentioned above, wherein a barrier rib to separate the sealing agent and the liquid crystal layer can be provided between the TFT substrate and the opposing substrate; and the sealing agent and the barrier rib can be in separation. In that case, conduction of heat into an electronic element-forming area can be suppressed.

(9) A method for manufacturing a display apparatus according to a fourth embodiment of the present invention comprises: preparing a first substrate; forming, above the first substrate or on a surface of the first substrate, an electronic element to compose pixel; preparing a second substrate and arranging a sealing agent material on one of the first substrate and the second substrate; superimposing the first substrate and the second substrate with the sealing agent material being sandwiched between the first substrate and the second substrate; and adhering the first substrate and the second substrate with the sealing agent material, wherein, a material comprising a low melting point glass material and a plurality of granular bodies is used for the sealing agent material, the plurality of granular bodies having a melting point being higher than a softening point of the low melting point glass material and being mixed into the low melting point glass material; in arranging the sealing agent material, the sealing agent material is arranged at a portion, wherein the portion surrounds an electronic element-forming area for the electronic element when the first substrate and the second substrate are superimposed; and the sealing agent material is adhered to the first substrate and the second substrate by irradiation with laser light.

According to the configuration of (9), it is possible to manufacture a display device in which an electronic element can be protect from moisture and oxygen and, even more, the gap between two substrates can be controlled accurately.

(10) In the method for manufacturing the display apparatus of (9) mentioned above, the sealing agent material in which a content rate of the plurality of granular bodies in an entirety of the plurality of granular bodies and the low melting point glass material is greater than or equal to 5 mass % and less than or equal to 30 mass % can be used. In this way, the sealing agent material can be adhered with a sufficient strength to the first and second substrates, and, even more, non-uniformity and dispersion of the gap between the first substrate and the second substrate can also be suppressed.

(11) In the method for manufacturing a display apparatus of (9) or (10) mentioned above, the irradiation with laser light can be carried out while exerting compressive force, on the sealing agent material, in the thickness direction of the first substrate and the second substrate. In this way, the gap between the first substrate and the second substrate can be strictly controlled.

(12) In the method for manufacturing a display apparatus of (11) mentioned above, a pressing jig being formed using quartz can be placed on the first substrate and the second substrate being superimposed; and the compressive force can be exerted via the pressing jig, and the sealing agent material can be irradiated via the pressing jig with laser light having a wavelength of greater than or equal to 300 nm and less than or equal to 2000 nm at the top of the pressing jig. In this way, the gap between the first substrate and the second substrate can be uniformly controlled over the whole of these substrates, and, moreover, the sealing agent material can be sufficiently irradiated with laser light.

(13) In the method for manufacturing a display apparatus of any one of (9) to (12) mentioned above, a glass frit is used as the low melting point glass material, and a columnar body or a spherical body constituted of an inorganic substance can be used as the granular bodies; and the sealing agent material can be arranged by applying the glass frit and the granular bodies to the first substrate or the second substrate using printing or dispensing. In that case, the sealing agent material can easily be arranged.

(14) In the method for manufacturing a display apparatus of any one of (9) to (12) mentioned above, a glass ribbon comprising the plurality of granular bodies and the low melting point glass material can be used for the sealing agent material; and the sealing agent material can be arranged by bonding the glass ribbon to a given portion of the first substrate or the second substrate. In this way, the first substrate and the second substrate can be adhered using a sealing agent having less air bubbles.

(15) In the method for manufacturing a display apparatus of (14) mentioned above, in bonding of the glass ribbon, the glass ribbon can be arranged to each of plural parts being divided parts of an adhering portion to be adhered with the sealing agent material, and one end or both ends of the glass ribbon can be adhered to the first substrate or the second substrate at a part being opposite to the electronic element-forming area with respect to the adhering portion. In this way, penetration of gas into an electronic element-forming area can be reduced.

### DESCRIPTION OF REFERENCE NUMERALS

10 First substrate (TFT Substrate)
13 Driving TFT
19 First insulating layer
20 Second substrate (Opposing substrate)
30 Electronic element
30a Organic-EL light-emitting element (OLED)
30b Liquid crystal display element (LCD)
31 First electrode (Anode electrode)
32 Second insulating layer (Insulating bank)
32a Third insulating layer
33 Organic layer
34 Second electrode (Cathode electrode)
35 Encapsulating layer (TFE)
41 Reflecting electrode (Pixel electrode)
42 Liquid crystal layer
43 Opposing electrode
50 Sealing agent
50a Low melting point glass material
50b Spacer
51 Sealing agent material
51b Glass ribbon
60 Barrier rib
61 Barrier rib material
100 Sealing structure
200 Display apparatus
A Electronic element-forming area
B Adhering part
P Pressing jig
R First region
T Second region

1. A sealing structure comprising:
a first substrate and a second substrate being arranged in an opposing manner;
an electronic element being formed between the first substrate and the second substrate; and
a sealing agent sealing a gap between the first substrate and the second substrate at an outer periphery of the electronic element, wherein
the sealing agent comprises a low melting point glass material and a plurality of spacers;
the plurality of spacers has a melting point being higher than a softening point of the low melting point glass material; and
each one of the plurality of spacers is a granular body having a grain diameter of greater than or equal to 5 μm and less than or equal to 50 μm.

2. The sealing structure according to claim 1, wherein
the low melting point glass material is a solidified material of glass frit being once softened; and
each one of the plurality of spacers is a granular body constituted of an inorganic substance and being mixed into the glass frit.

3. The sealing structure according to claim 1, wherein the softening point of the low melting point glass material is greater than or equal to 400° C. and less than or equal to 500° C., and the plurality of spacers is formed using quartz.

4. The sealing structure according to claim 1, wherein a content rate of the plurality of spacers in the sealing agent is greater than or equal to 5 mass % and less than or equal to 30 mass %.

5. The sealing structure according to claim 1, wherein
a barrier rib being separated from the sealing agent and surrounding the electronic element is formed between the sealing agent and the electronic element, the barrier rib comprising a plurality of pores.

6. An organic-EL display apparatus comprising
the sealing structure according to claim 1, wherein
the electronic element is an organic-EL light-emitting element.

7. A display apparatus comprising:
a TFT substrate comprising a drive element being formed for each pixel of a display, screen and a first insulating layer planarizing a surface above the drive element;
a reflecting electrode for a liquid crystal display element, the reflecting electrode being formed above the first insulating layer in a first region of one pixel of the TFT substrate;
an organic-EL light-emitting element being formed in a second region of the one pixel, the second region being adjacent to the first region and being above the first insulating layer of the TFT substrate, the organic-EL light-emitting element comprising a first electrode, an organic layer, a second electrode and an encapsulating layer;
an opposing substrate comprising an opposing electrode opposing the reflecting electrode, the opposing substrate being arranged in an opposing manner to the TFT substrate;
a liquid crystal layer being filled between the TFT substrate and the opposing substrate; and
a sealing agent sealing a gap between the TFT substrate and the opposing substrate at an outer periphery of the liquid crystal layer, wherein
the sealing agent comprises a low melting point glass material and a plurality of spacers; and
the plurality of spacers has a melting point being higher than a softening point of the low melting point glass material.

8. The display apparatus according to claim 7, wherein
a barrier rib to separate the sealing agent and the liquid crystal layer is provided between the TFT substrate and the opposing substrate; and
the sealing agent and the harrier rib are in separation.

9. A method for manufacturing a display apparatus, the method comprising:
preparing a first substrate;
forming, above the first substrate or on a surface of the first substrate, an electronic element to compose a pixel;
preparing a second substrate and arranging a sealing agent material on one of the first substrate and the second substrate;
superimposing the first substrate and the second substrate with the sealing agent material being sandwiched between the first substrate and the second substrate; and
adhering the first substrate and the second substrate with the sealing agent material, wherein,
a material comprising a low melting point glass material and a plurality of granular bodies is used for the sealing agent material, the plurality of granular bodies having a inciting point being higher than a softening point of the low melting point glass material and being mixed into the low melting point glass material;
each one of the plurality of granular bodies has a grain diameter of greater than or equal to 5 μm and less than or equal to 50 μm;
in arranging the sealing agent material, the sealing agent material is arranged at a portion, wherein the portion surrounds an electronic element-forming area for the electronic element when the first substrate and the second substrate are superimposed; and
the sealing agent material is adhered to the first substrate and the second substrate by irradiation with laser light.

10. The method for manufacturing a display apparatus according to claim 9, wherein the sealing agent material in which a content rate of the plurality of granular bodies in an entirety of the plurality of granular bodies and the low melting point glass material is greater than or equal to 5 mass % and less than or equal to 30 mass % is used.

11. The method for manufacturing a display apparatus according to claim 9, wherein the irradiation with laser light is carried out white exerting compressive force, on the sealing agent material, in the thickness direction of the first substrate and the second substrate.

12. The method for manufacturing a display apparatus according to claim 11, wherein
a pressing jig being formed using quartz is placed on the first substrate and the second substrate being superimposed; and
the compressive force is exerted via the pressing jig, and
the sealing agent material is irradiated via the pressing jig with laser light having a wavelength of greater than or equal to 300 nm and less than or equal to 2000 nm at the top of the pressing jig.

13. The method for manufacturing a display apparatus according to claim 9, wherein,
a glass frit is used as the low melting point glass material, and a columnar body or a spherical body constituted of an inorganic substance is used as the granular bodies; and
the sealing agent material is arranged by applying the glass frit and the granular bodies to the first substrate or the second substrate using printing or dispensing.

14. The method for manufacturing a display apparatus according to claim 9, wherein,
a glass ribbon comprising the plurality of granular bodies and the low melting point glass material is used for the sealing agent material; and
the sealing agent material is arranged by bonding the glass ribbon to a given portion of the first substrate or the second substrate.

15. The method for manufacturing a display apparatus according to claim 14, wherein, in bonding of the glass ribbon,
the glass ribbon is arranged to each of plural parts being divided parts of an adhering portion to be adhered with the sealing agent material, and
one end or both ends of the glass ribbon is adhered to the first substrate or the second substrate at a part being opposite to the electronic element-forming area with respect to the adhering portion.

16. The sealing structure according to claim 1, wherein
the electronic element comprises a plurality of pixels composing a display screen;
each one of the plurality of pixels comprises a region constituting a liquid crystal display element and a region being provided with an organic-EL tight-emitting element.

17. The sealing structure according to claim 5, wherein
each one of the plurality of spacers is a granular body, and
a height of the barrier rib is less than a grain diameter of the granular body.

18. The method for manufacturing a display apparatus according to claim 9, further comprising forming a liquid crystal display element in a first region of the pixel, wherein
forming the electronic element comprises forming an organic-EL light-emitting element in a second region of the pixel.

19. The method for manufacturing a display apparatus according to claim 9, further comprising forming a barrier rib to surround the electronic element between the sealing agent material and the electronic element, so as to be separated from the sealing agent material, wherein
forming the barrier rib comprises forming a plurality of pores in the barrier rib.

20. The method for manufacturing a display apparatus according to claim 15, wherein
the glass ribbon is adhered to the first substrate or the second substrate using an adhering agent at an exterior to the adhering portion so that gas released from the adhering agent is prevented from penetrating into the electronic element-forming area.
